(19) United States
(12) Patent Application Publication
(10) Pub. No.: US 2011/0316658 A1
(43) Pub. Date: Dec. 29, 2011

(54) THIN TYPE COMMON MODE FILTER AND METHOD OF MANUFACTURING THE SAME

(75) Inventor: SHIH KWAN LIU, Hsinchu City (TW)

(73) Assignee: INPAQ TECHNOLOGY CO., LTD., MIAOLI (TW)

(21) Appl. No.: 12/954,786

(22) Filed: Nov. 26, 2010

(30) Foreign Application Priority Data
Jun. 28, 2010 (TW) 099120989

(51) Int. Cl. H01F 5/00; H05K 3/30

(52) U.S. Cl. 336/200; 29/832

(57) ABSTRACT

A thin type common mode filter includes an insulating flexible substrate, a first magnetic material layer, a first coil leading layer, a coil main body multi-layer, a second coil leading layer, and a second magnetic material layer. The first coil leading layer is formed on a first surface of the flexible substrate, and the first coil leading layer is formed on a second surface of the flexible substrate opposite to the first surface. The coil main body multi-layer, the second coil leading layer, and the second magnetic material layer are sequentially stacked on the first coil leading layer.

### BACKGROUND OF THE INVENTION

1. Field of the Invention

The present invention relates to a common mode filter and a manufacturing method thereof, and more particularly to a thin type common mode filter and a method of manufacturing the same.

2. Description of the Related Art

Common mode filters are components for suppressing common mode currents causing electromagnetic interference between two parallel transmission lines. In order to be used in current portable communication devices, common mode filters are required to be of a compact size and to have a highly densified structure. As such, thin type common mode filters and multilayer common mode filters are gradually replacing conventional wire-wound type common mode filters. As indicated by its name, a wire-wound type common mode filter is mainly constituted by a ferrite core wound by a coil. The manufacture of thin type or multilayer common mode filters requires more processes than that of conventional wire-wound type common mode filters. For example, the planar coil of a thin type common mode filter is usually formed on a ferrite plate using photolithography, and the coil of a multilayer common mode filter is formed using a screen printing technique and fired at high temperature.

In order to adjust the common mode impedance of a coil circuit, U.S. Pat. No. 7,145,427 B2 discloses a method for forming a common mode filter. The method initially forms a coil circuit on a magnetic substrate, and then holes are formed on the portion without the coil circuit, a mixture of resin and magnetic powders is filled in the holes, and finally another magnetic substrate is bonded to the magnetic substrate with the coil circuit by a bonding process after a surface planarization process is applied to the magnetic substrate with the coil circuit. The patent teaches that the common mode impedance can be adjusted by changing the thickness of dielectric layers. According to the teaching of the patent, the thickness of dielectric layers is a major influence on the common mode impedance. However, the type of processes adopted, process parameters, and the characteristics of dielectric material decide the thickness of a dielectric layer, and controlling the thickness in a precise range is not easy and increases manufacturing cost.

U.S. Pat. No. 6,356,181 B1 and U.S. Pat. No. 6,618,929 B2 disclose multilayer common mode filters. The disclosed multilayer common mode filters both include a coil structure formed on a magnetic substrate and a top cover of magnetic material covering the coil structure. The two patents teach reducing the impedance for differential signals by changing particular patterns of the coil structure. However, the coil structure is connected by several sections, which are separately formed on different layers. Such a change is complex, and involves many process variables.

Conventional common mode filters usually need sheets or substrates with low dielectric loss, and the material of the sheet or substrate is mostly selected from ferrite (magnet), aluminum oxide (Al₂O₃), aluminum nitride (AlN), glass, and quartz. The sheet or substrate used in the related art is a sintered ceramic substrate of ferrite (magnet), aluminum oxide or aluminum nitride, a fired non-ceramic substrate of glass or quartz, or a composite substrate formed by a mixture of the above-mentioned material and resin.

There are limitations on the thicknesses of the above sheets or substrates. The sheets or substrates having a thickness of greater than 300 micrometers are more easily mass produced, whereas sheets or substrates with thickness below 300 micrometers are expensive and unsuitable for mass production. However, the manufacturing method of the thick sheets or substrates is complex and time-consuming, and the manufacturing cost is high. Furthermore, use of the thicker sheets or substrates in common mode filters causes the filters to be excessively thick, so the sheets and substrates greater than 300 micrometers are unfavorable to the manufacture of light and thin common mode filters.

The term “substrate” is defined as a plate, which is treated at a temperature of above 600 degrees Celsius and does not contain polymer. The term “sheet” is defined as a plate, which is not treated at a temperature of above 600 degrees Celsius and contains polymer. In the above substrates and sheets, the industry of manufacturing aluminum oxide substrates is mature, and the price of such products is determined by market supply and demand. Because other sheets and substrates are rarely used, the supply of aluminum oxide substrates is limited, and the manufacturing technology thereof is not well developed. As a result, the price is affected by the limited number of suppliers.

Commonly used substrates or sheets with thickness of below 300 micrometers are fiberglass substrates used for manufacturing printed circuit boards. However, the thickness of fiberglass substrates, around 200 micrometers, cannot be easily reduced, and dielectric loss of fiberglass substrates is high, around 100 times that of ferrite (magnet), aluminum oxide (Al₂O₃), aluminum nitride (AlN), glass, and quartz.

As to thin substrates of polymer material such as polypropylene or polythene, thin polymer substrates are easily obtained but their dielectric loss is high. In addition to high dielectric loss, polymer material cannot sustain its shape and is easily deformed by the high temperature reflow process required for the attachment of electronic components.

In summary, a thin common mode filter and a method of manufacturing the same are needed such that conventional common mode filters with the above disadvantages can be replaced, and the related manufacturing cost can be reduced.

### SUMMARY OF THE INVENTION

The present invention provides a thin type common mode filter with a simple structure. The thin type common mode filter uses an insulating flexible sheet as its substrate. The flexible sheet is thin, and can sustain high reflow temperature. Thus, the thin type common mode filter has advantages of low thickness and ability to withstand convenient manufacturing processes.

The present invention provides a low cost method of manufacturing a common mode filter. The use of an insulating flexible sheet as the substrate allows continuous production, the formation of low dielectric loss structures, and no additional manufacturing cost.

In summary, the present invention discloses a thin type common mode filter comprising an insulating flexible substrate, a first coil leading layer, a first magnetic material layer, a coil main body multi-layer, a second coil leading layer, and a second magnetic material layer. The first coil leading layer is formed on a first surface of the flexible substrate. The first magnetic material layer is formed on a second surface of the flexible substrate opposite to the first surface. The coil main body multi-layer, the second coil leading layer, and the second magnetic material layer are sequentially formed on the first coil leading layer.

The present invention discloses a method of manufacturing a thin type common mode filter comprising the steps of: providing an insulating flexible substrate, forming a first coil leading layer on a first surface of the flexible substrate, forming a first magnetic material layer formed on a second surface of the flexible substrate opposite to the first surface, forming a coil main body multi-layer on the first coil leading layer, forming a second coil leading layer on the coil main body multi-layer, and forming a second magnetic material layer on the second coil leading layer.

Other objectives, advantages and novel features of the invention will become apparent from the following detailed description when read in conjunction with the accompanying drawings.

### BRIEF DESCRIPTION OF THE DRAWINGS

The invention will be described according to the appended drawings in which:

FIG. 1 is a perspective exploded view showing a thin type common mode filter according to one embodiment of the present invention;

FIG. 2 is a perspective exploded view showing a thin type common mode filter according to another embodiment of the present invention;

FIGS. 3A through 3J are sectional views showing respective steps of a method of manufacturing a thin type common mode filter according to one embodiment of the present invention; and

FIG. 4 is a cross-sectional view showing a thin type common mode filter according to another embodiment of the present invention.

### DETAILED DESCRIPTION OF THE INVENTION

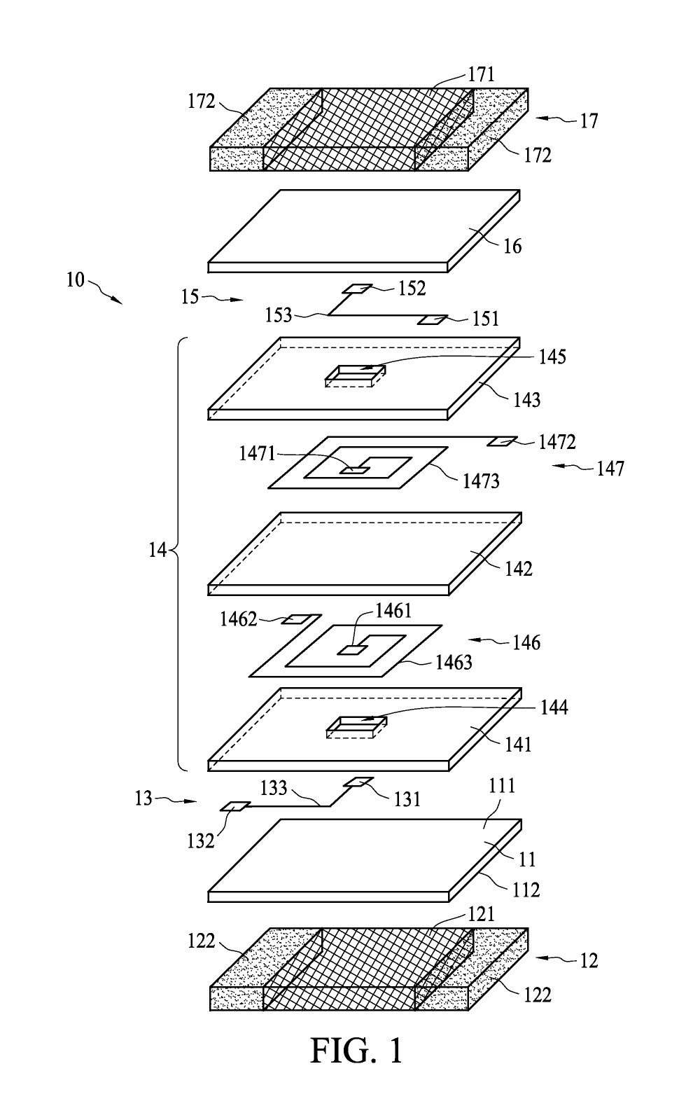

FIG. 1 is a perspective exploded view showing a thin type common mode filter according to one embodiment of the present invention. Referring to FIG. 1, a thin type common mode filter 10 comprises an insulating flexible substrate 11, a first magnetic material and non-magnetic material layer assembly 12, a first coil leading layer 13, a coil main body multi-layer 14, a second coil leading layer 15, a fourth insulating layer 16, and a second magnetic material and non-magnetic material layer assembly 17. The first insulating layer 141, the first coil body layer 146, the second insulating layer 142, the second coil body layer 147, and the third insulating layer 143 are included in the coil main body multi-layer 14.

The insulating flexible substrate 11 can be a flexible printed circuit board, selectively formed of polyimide. Other materials with low dielectric loss and ability to sustain to high reflow temperature are suitable for the flexible substrates 11.

With better electrical and mechanical characteristics, polyimide is preferable for use in manufacturing the flexible substrate 11. For example, polyimide can sustain low and high temperatures, including continuous use at 288 degrees Celsius, intermittent use at 480 degrees Celsius, and use below one degree Kelvin. Polyimide has high wear resistance, which is over ten times of that of general engineering plastics without lubrication. Polyimide also has high resistance to rocking-impact wear. Polyimide is not easily deformed and can withstand high loading, creeping only 0.6% at a temperature of 260 degrees Celsius under stress of 180 kg/cm² for 1000 hours. Polyimide has dielectric strength of 22 KV/mm and good resistance against plasma and radiation. Polyimide is resistant against lubricants, oils, and solvents. Polyimide has good machinability. In addition, benzocyclobutene can also be used to manufacture the flexible substrate 11.

Manufacture of polyimide sheets or substrates is a mature technique. Generally, polyimide sheets or substrates can be formed with a thickness below 50 micrometers. Presently, the available thickness specifications of conventional commercial products are 17.5, 35, and 50 micrometers. Compared to traditional ceramic and non-ceramic substrates with thickness above 300 micrometers, the commercial polyimide sheets or substrates are significantly thinner. Usually, common mode filters manufactured by thin film processes have main circuit bodies with a thickness of about 50 micrometers. If traditional substrates with 300-micrometer thickness are used, the thickness of common mode filters may increase remarkably.

The first magnetic material and non-magnetic material layer assembly 12 is formed on a second surface 112 of the flexible substrate 11 by a screen-printing process or a coating process, comprising a first magnetic material layer 121 and a first non-magnetic material layer 122, wherein the first non-magnetic material layer 122 are on two sides of the first magnetic material layer 121. The patterns of the first magnetic material layer 121 and the first non-magnetic material layer 122 of the present embodiment do not limit the claim scopes of the present invention. Other patterns are also applicable, including an embodiment of the present invention in which the second surface 112 is merely covered by the first magnetic material layer 121. The first magnetic material layer 121 can be a magnetic substrate or an adhesive body mixed with magnetic powders. The adhesive body may be obtained by blending magnetic powders into polyimide, epoxy resin, benzocyclobutene, or other polymer materials.

The first coil leading layer 13 is formed on a first surface 111 of the flexible substrate 11, comprising a first electrode 131, a second electrode 132, and a wire 133 connecting the first electrode 131 and the second electrode 132. A first insulating layer 141 covers the first coil leading layer 13 with a connecting hole formed therethrough for connecting the first electrode 13 and the spiral coil circuit in the coil main body multi-layer 14.

The first coil body layer 146 is disposed on the first insulating layer 141, comprising a first electrode 1461, a second electrode 1462, and a spiral coil 1463. The second insulating layer 142 is disposed between the first coil body layer 146 and the second coil body layer 147. The second coil body layer 147 also comprises a first electrode 1471, a second electrode 1472, and a spiral coil 1473. A third insulating layer 143 is disposed on the second coil body layer 147 with a connecting hole 145 formed therethrough for connecting the first electrode 1471 and the second coil leading layer 15. The second coil leading layer 15 includes a first electrode 151, a second electrode 152, and a wire 153 connecting the first electrode 151 and the second electrode 152. The fourth insulating layer 16 disposed on the second coil leading layer 15 can be an adhesive bonding layer, and the second magnetic material and non-magnetic material layer assembly 17 is disposed on the fourth insulating layer 16. The second magnetic material and non-magnetic material layer assembly 17 includes a second magnetic material layer 171 and a non-magnetic material layer 172.

In one embodiment, the area of the first magnetic material layer 121 is configured to overlap the projected areas of the first and second coil body layers 146 and 147.

In one embodiment, the coil main body multi-layer 14 may include, but is not limited to, a set of spiral coils. Alternatively, multiple sets of spiral coils can be formed in the same common mode filter.

The material of the first coil leading layer 13, the first coil body layer 146, the second coil body layer 147, and the second coil leading layer 15 comprises silver (Ag), palladium (Pd), aluminum (Al), chromium (Cr), nickel (Ni), titanium (Ti), gold (Au), copper (Cu), or platinum (Pt).

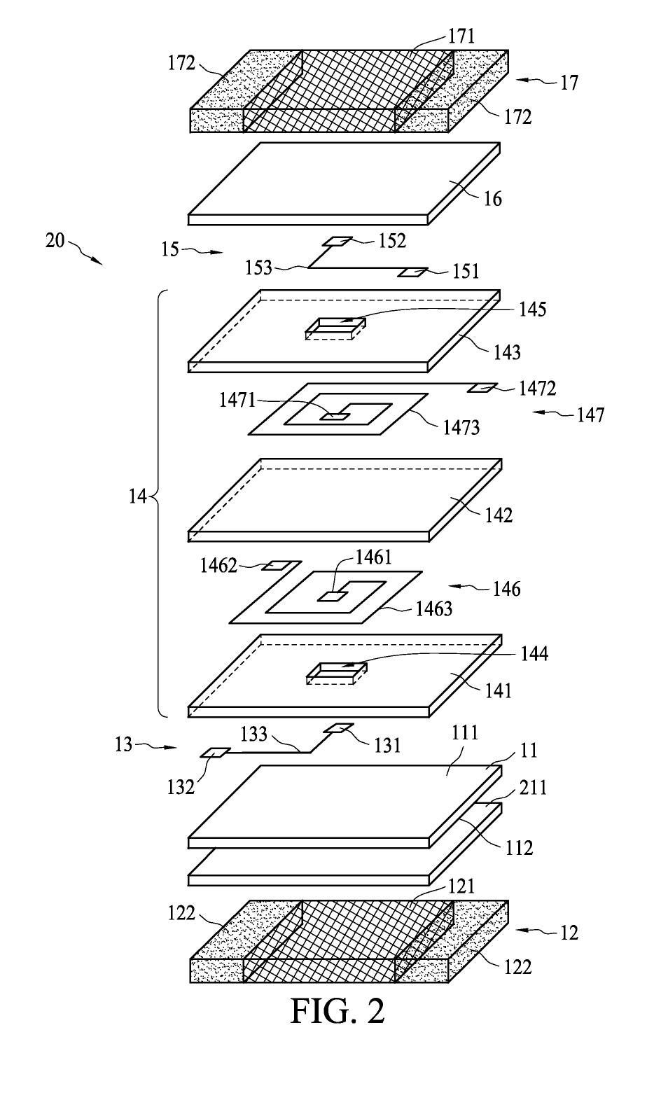

FIG. 2 is a perspective exploded view showing a thin type common mode filter according to another embodiment of the present invention. Referring to FIG. 2, a common mode filter 20 comprises an insulating flexible substrate 11, a first magnetic material and non-magnetic material layer assembly 12, a fifth insulating layer 112, a first coil leading layer 13, a coil main body multi-layer 14, a second coil leading layer 15, a fourth insulating layer 16, and a second magnetic material and non-magnetic material layer assembly 17. Compared with the common mode filter 10 in

FIG. 1, the common mode filter 20 in FIG. 2 includes a fifth insulating layer 211 formed between the flexible substrate 11 and the first magnetic material and non-magnetic material layer assembly 12. The fifth insulating layer 211 can be an adhesive bonding layer thereby bonding the flexible substrate 11 and the first magnetic material and non-magnetic material layer assembly 12 together.

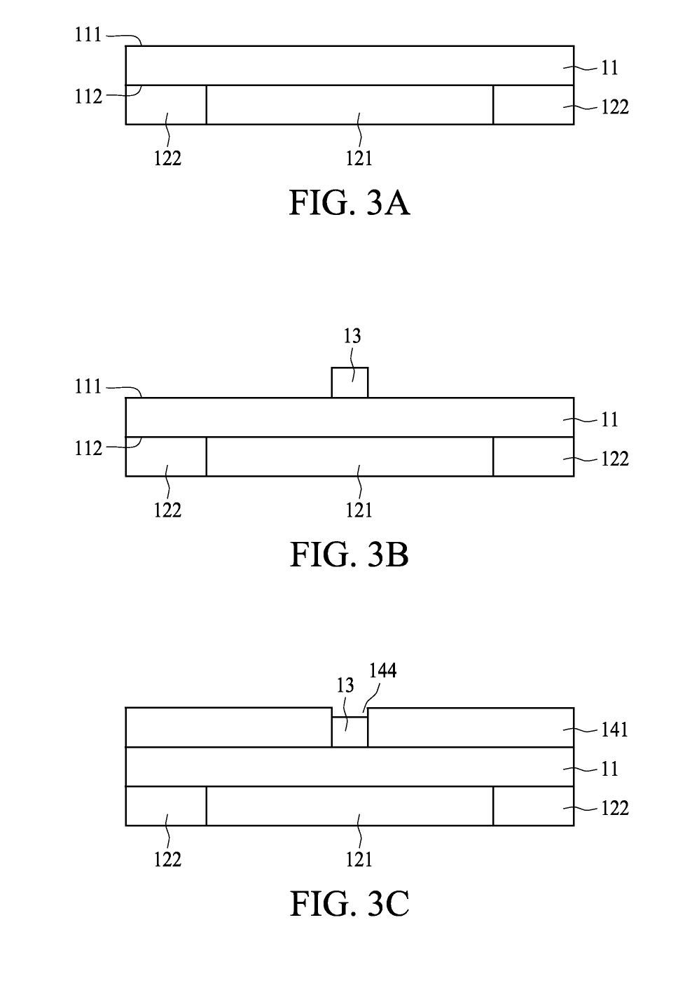

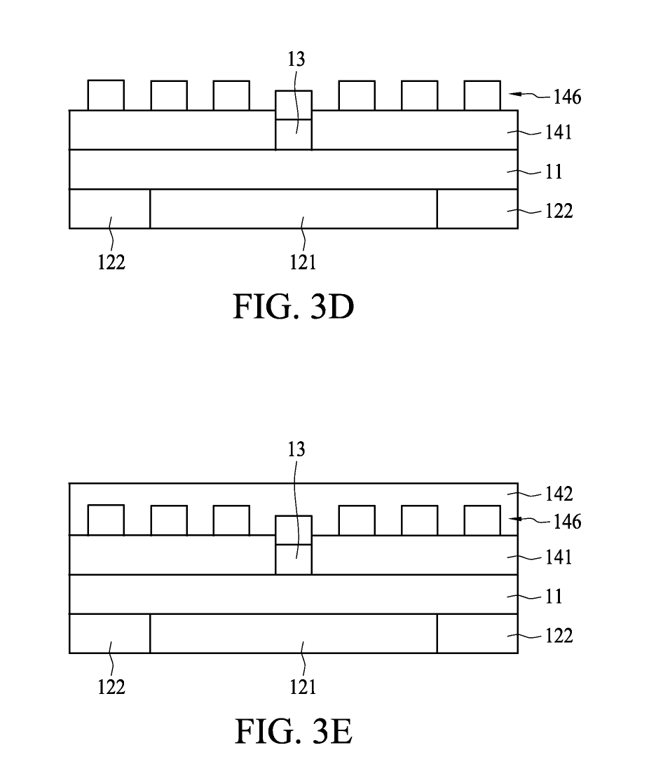

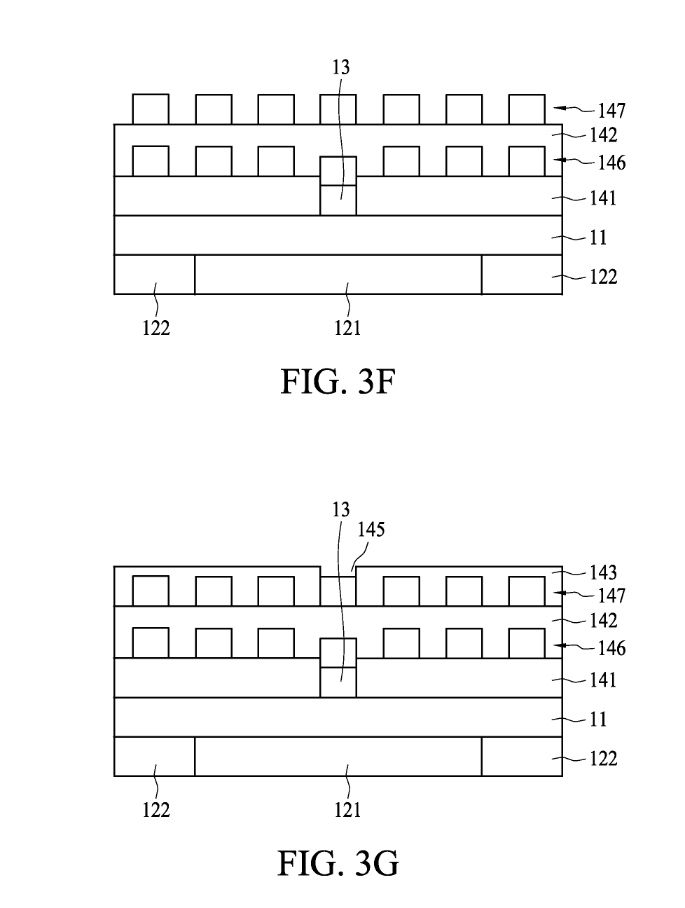

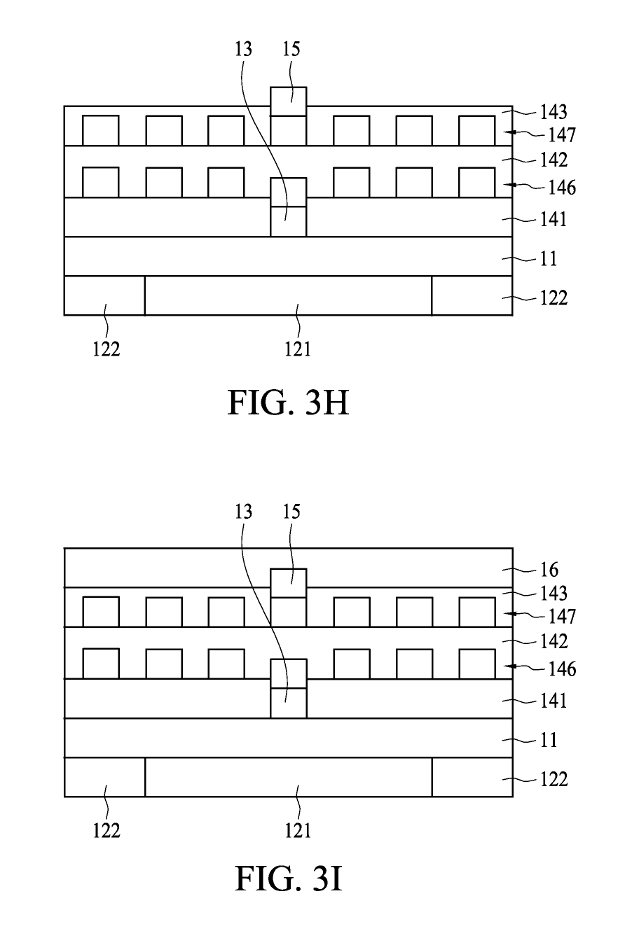

FIGS. 3A through 3J are sectional views showing respective steps of a method of manufacturing a thin type common mode filter according to one embodiment of the present invention. Referring to FIG. 3A, a screen-printing process or a coating process is employed to form a first magnetic material layer 121 and a first non-magnetic material layer 122 on a second surface 112 of a flexible substrate 11.

As shown in FIG. 3B, a first coil leading layer 13 is manufactured using a metal deposition process, a photolithographic process, and an electroplating process. Next, a first insulating layer 141 is coated, and a photolithographic process and an etch process are used to form a connecting hole 144 for connecting upper and lower electrodes as shown in FIG. 3C. A thin film deposition process, a photolithographic process, or an electroplating process is applied again for manufacturing a first coil body layer 146 as shown in FIG. 3D. A second insulating layer 142 is coated as illustrated in FIG. 3E. A second coil body layer 147, as shown in FIG. 3F, is formed by a thin film deposition process, a photolithographic process, or an electroplating process. A third insulating layer 143 is coated, on which a connecting hole 145 for electrode connection is formed using a photolithographic process or an etch process, as shown in FIG. 2G. A second coil leading layer 15 is formed using a thin film deposition process, a photolithographic process, or an electroplating process as shown in FIG. 3H. A fourth insulating layer 16 is coated on a surface of the second coil leading layer 15, as shown in FIG. 3I. The second magnetic material and non-magnetic material layer assembly 17 is formed on the fourth insulating layer 16 using a bonding process, a screen-printing process, or a spin-coating process as shown in FIG. 3J.

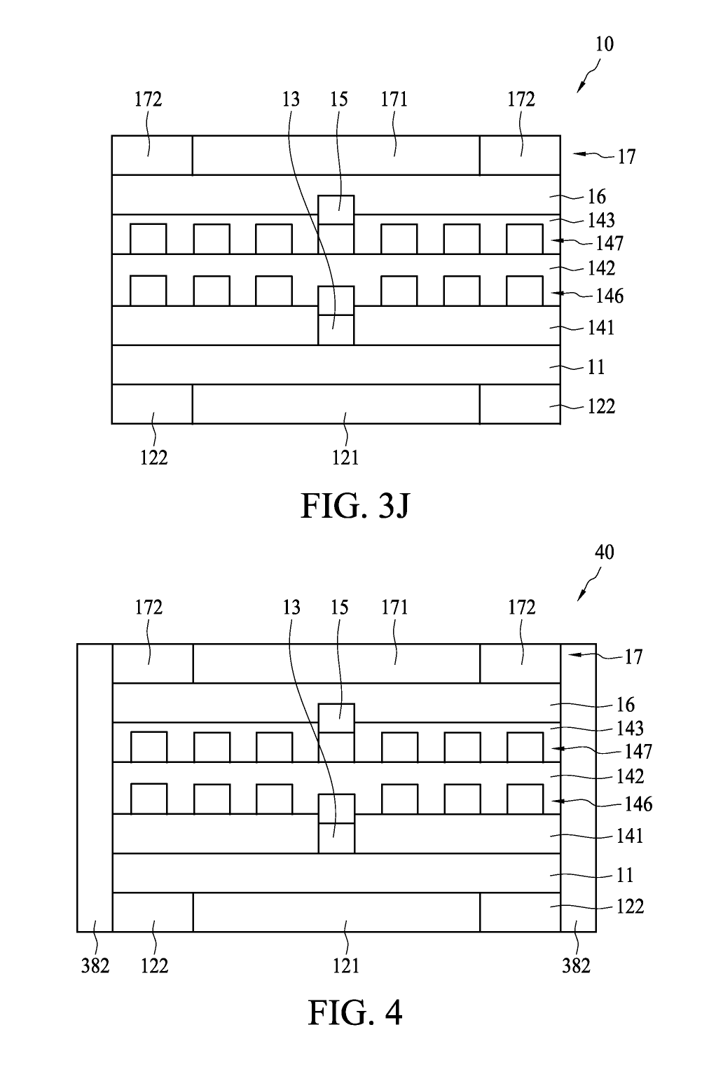

FIG. 4 is a cross-sectional view showing a thin type common mode filter according to another embodiment of the present invention. Compared with the common mode filter 10 in FIG. 3J, the two sides of the common mode filter 40, on which no external electrode is formed, are covered respectively by magnetic material layers (third and fourth magnetic material layers) 382.

The polyimide sheet used in the embodiments of the present invention is a rollable sheet. Thin film coils and insulating layers are formed in sequence on the polyimide sheet using a spin-coating process, a photolithographic process, a plasma-enhanced chemical vapor deposition (PECVD) process, an electroplating process, and an etch process. Upper thick film layers of magnetic material are formed at desired locations, usually right above inner coils, using a screen-printing process. Finally, on the back side of the polyimide sheet, lower thick film layers of magnetic material are formed at desired locations, usually right below the inner coils, but not on the entire back side of the polyimide sheet. The manufacture of the common mode filters is substantially completed.

The above-mentioned etch process may be a dry etch process or a wet etch process. The dry etch process comprises a reactive ion etch process, and the wet etch process comprises chemical wet etch process.

As shown in the above steps, the present invention sequentially forms insulating layers and coils on a rollable low dielectric loss polyimide sheet, and magnetic material and non-magnetic material layer assemblies separately formed on the upper and lower surfaces of the polyimide sheet by a screen-printing process. Using the afore-mentioned process steps, a low cost thin type common mode filter can be manufactured. All steps of the entire process are simple.

The embodiment of FIG. 1 shows a structure of a single common mode filter; however, the present invention can be used to manufacture an array of common mode filter structures.

The above-described embodiments of the present invention are intended to be illustrative only. Numerous alternative embodiments may be devised by persons skilled in the art without departing from the scope of the following claims.

What is claimed is:

1. A thin type common mode filter, comprising:
an insulating flexible substrate;
a first coil leading layer formed on a first surface of the flexible substrate;
a first magnetic material layer formed on a second surface of the flexible substrate opposite to the first surface;
a coil main body multi-layer formed on the first coil leading layer;
a second coil leading layer formed on the coil main body multi-layer; and
a second magnetic material layer formed on the second coil leading layer.

2. The thin type common mode filter of claim 1, wherein the flexible substrate comprises polyimide or benzocyclobutene.

3. The thin type common mode filter of claim 1, wherein the flexible substrate has a thickness of less than 50 micrometers.

4. The thin type common mode filter of claim 1, wherein the coil main body multi-layer comprises, in stacked sequence, a first insulating layer, a first coil body layer, a second insulating layer, a second coil body layer, and a third insulating layer, and each of the first and second coil body layers comprises at least one coil circuit.

5. The thin type common mode filter of claim 4, further comprising a fourth insulating layer disposed between the second magnetic material layer and the second coil leading layer.

6. The thin type common mode filter of claim 5, further comprising a fifth insulating layer disposed between the flexible substrate and the first magnetic material layer.

7. The thin type common mode filter of claim 4, further comprising a first non-magnetic material layer disposed on the second surface.

8. The thin type common mode filter of claim 7, wherein the first non-magnetic material layer is disposed on two sides of the first magnetic material layer, and area of the first magnetic material layer is configured to overlap projected areas of the first and second coil body layers.

9. The thin type common mode filter of claim 5, further comprising a second non-magnetic material layer, wherein the second magnetic material layer and the second non-magnetic material layer are disposed on a surface of the fourth insulating layer.

10. The thin type common mode filter of claim 6, wherein the first, second, third, fourth, and fifth insulating layers comprise polyimide, epoxy, or benzocyclobutene.

11. The thin type common mode filter of claim 4, wherein the first coil leading layer, the first coil body layer, the second coil body layer, and second coil leading layer are formed of silver, palladium, aluminum, chromium, nickel, titanium, gold, copper, or platinum.

12. The thin type common mode filter of claim 1, wherein the first and second magnetic material layers are formed of a mixture of resin and magnetic powders.

13. The thin type common mode filter of claim 12, wherein the resin comprises polyimide, epoxy, or benzocyclobutene.

14. The thin type common mode filter of claim 1, further comprising a third magnetic material layer, a fourth magnetic material layer, and external electrodes, wherein the third and fourth magnetic material layers are on sides of the thin type common mode filter without external electrodes.

15. A method of manufacturing a thin type common mode filter, comprising the steps of:
providing an insulating flexible substrate;
forming a first coil leading layer on a first surface of the flexible substrate;
forming a first magnetic material layer formed on a second surface of the flexible substrate opposite to the first surface;
forming a coil main body multi-layer on the first coil leading layer;
forming a second coil leading layer on the coil main body multi-layer; and
forming a second magnetic material layer on the second coil leading layer.

16. The method of claim 15, wherein the step of forming a coil main body multi-layer comprises the steps of:
forming a first insulating layer on the first coil leading layer;
forming at least one first connecting hole on the first insulating layer;
forming a first coil body layer on the first insulating layer;
depositing a second insulating layer on the first coil body layer;
forming a second coil body layer on the second insulating layer;
depositing a third insulating layer on the second coil body layer; and
forming at least one second connecting hole on the third insulating layer.

17. The method of claim 16, wherein the first coil leading layer, the first coil body layer, the second coil body layer, and the second coil leading layer are each formed using a metal deposition process, a photolithographic process, or an electroplating process.

18. The method of claim 16, further comprising a step of forming a fourth insulating layer on the second coil leading layer.

19. The method of claim 15, further comprising a step of forming a first non-magnetic material layer on the second surface.

20. The method of claim 18, further comprising a step of forming a second non-magnetic material layer, wherein the second non-magnetic material layer and the second magnetic material layer are on a surface of the fourth insulating layer.

21. The method of claim 18, further comprising a step of forming a fifth insulating layer between the flexible substrate and the first coil leading layer.

22. The method of claim 21, wherein the the first, second, third, fourth, and fifth insulating layers comprise polyimide, epoxy, or benzocyclobutene.

23. The method of claim 15, wherein flexible substrate comprises polyimide or benzocyclobutene

24. The method of claim 16, wherein the first coil leading layer, the first coil body layer, the second coil body layer, and second coil leading layer are formed of silver, palladium, aluminum, chromium, nickel, titanium, gold, copper, or platinum.

25. The method of claim 16, wherein the first and second connecting holes are formed using a photolithographic process and an etch process.

26. The method of claim 25, wherein the etch process comprises a dry etch process or a wet etch process, and the dry etch process comprises a reactive ion etch process and the wet etch process comprises a wet chemical etch process.
